(19) United States
(12) Patent Application Publication
(10) Pub. No.: US 2015/0052747 A1
(43) Pub. Date: Feb. 26, 2015

(54) MANUFACTURING METHOD OF TOUCH SUBSTRATE

(71) Applicant: Chih-Chung Lin, Taipei City (TW)

(72) Inventor: Chih-Chung Lin, Taipei City (TW)

(21) Appl. No.: 13/973,990

(22) Filed: Aug. 22, 2013

(51) Int. Cl. H05K 3/10

(52) U.S. Cl. CPC H05K 3/108
USPC 29/846

(57) ABSTRACT

A manufacturing method of touch substrate includes steps of: providing a substrate, a photosensitive film of Nano-Silver particles being formed on a surface of the substrate; performing an exposure process to the film of Nano-Silver particles of the surface of the substrate; performing a development process to the film of Nano-Silver particles of the surface of the substrate to form a nontransparent sensing electrode layer and a nontransparent electrode wiring layer in the form of a mesh on the surface of the substrate; and performing a high electrical conductivity treatment and a stabilization treatment to the nontransparent sensing electrode layer on the surface of the substrate. So, the nontransparent sensing electrode layer and nontransparent electrode wiring layer can be formed on the surface of the substrate at the same time. Therefore, the manufacturing process is simplified. Moreover, the surface resistance is lowered and the wiring space is enlarged.

### BACKGROUND OF THE INVENTION

1. Field of the Invention

The present invention relates generally to a manufacturing method of touch substrate, and more particularly to a manufacturing method of touch substrate, which is simplified. The touch substrate made by means of the manufacturing method has a lower surface resistance. Also, the wiring space of the touch substrate is enlarged.

2. Description of the Related Art

Touch panels have been widely applied to various fields in modern life. The touch panel can be integrated with the display panel, whereby a user can touch the display menu to control the electronic device to execute the corresponding command. The conductive film of the current touch panel is a film of indium tin oxide (ITO) or Nano-Silver-yarns. The conductive film (or so-called transparent electrode layer) is formed on the transparent substrate such as a glass substrate or polyethylene terephthalate (PET) substrate. The film of Nano-Silver-yarns is composed of multiple Nano-Silver-yarns.

The conventional conductive film such as film of indium tin oxide (ITO) or Nano-Silver-yarns is formed on the transparent substrate in such a manner that after a photoresist is coated on the conductive film on the surface of the transparent substrate, the conductive film on the surface of the substrate is baked. After baked, exposure and development processes are performed to form transparent electrode layer with an electrode pattern on the surface of the substrate. With the film of

Nano-Silver-yarns taken as an example, the transparent electrode layer on the surface of the substrate is composed of multiple Nano-Silver-yarns. The transparent electrode layer on the surface of the substrate is sequentially washed, etched, washed and baked. Then the transparent electrode layer on the surface of the substrate goes through a halftone printing process to form a wiring layer on the periphery of the surface of the substrate in connection with the adjacent transparent electrode layer. Then the substrate is baked again to achieve a touch substrate.

The touch substrate of the touch panel can be made by means of the above conventional manufacturing method. However, such manufacturing method has a problem. That is, the touch substrate needs to be manufactured by many complicated steps. Moreover, the low surface resistance of the film of Nano-Silver-yarns is about 50 ohms/□, while the lower surface resistance of the film of indium tin oxide (ITO) is about 150 ohms/□. The lower the surface resistance of the film of indium tin oxide (ITO) is, the better the conductivity is. However, in this case, the thickness of the film of indium tin oxide (ITO) must be increased. This will lead to deterioration of permeability of the film of indium tin oxide (ITO). Therefore, the surface resistance of the film of indium tin oxide (ITO) will affect the thickness and permeability of the film of indium tin oxide (ITO). As a result, the smaller the surface resistance is, the higher the cost is and the higher the technical threshold is. Therefore, the surface resistance can be hardly lowered.

Furthermore, the wiring layer is formed by means of halftone printing. As a result, the wiring space on the surface of the substrate is limited.

According to the above, the conventional touch substrate has the following shortcomings:
1. The manufacturing process is complicated.
2. The cost is higher.
3. The wiring space is limited.

### SUMMARY OF THE INVENTION

It is therefore a primary object of the present invention to provide a touch substrate, which is manufactured by a simplified process and has a lower surface resistance.

It is a further object of the present invention to provide the above touch substrate, which has an enlarged wiring space.

It is still a further object of the present invention to provide a manufacturing method of touch substrate, in which the nontransparent sensing electrode layer and nontransparent electrode wiring layer are formed on the surface of the substrate at the same time. Therefore, the manufacturing process is simplified. Moreover, the surface resistance is lowered.

It is still a further object of the present invention to provide the above manufacturing method of touch substrate. The touch substrate made by means of the manufacturing method has an enlarged wiring space.

To achieve the above and other objects, the touch substrate of the present invention is applied to a touch device. The touch substrate includes a substrate, at least one nontransparent sensing electrode layer and a nontransparent electrode wiring layer. The substrate has a first surface and a second surface opposite to the first surface. The nontransparent sensing electrode layer is formed on the first surface of the substrate. The nontransparent sensing electrode layer has multiple Nano-Silver particles and multiple nontransparent sensing blocks. The nontransparent sensing blocks are formed of the Nano-Silver particles, which are arranged in the form of a mesh. The nontransparent electrode wiring layer is formed on the periphery of the first surface of the substrate correspondingly in adjacency to and in connection with the nontransparent sensing electrode layer. According to the above arrangement of the touch substrate of the present invention, the manufacturing process is simplified and the surface resistance is lowered. Moreover, the wiring space is enlarged.

The manufacturing method of touch substrate of the present invention includes steps of: providing a substrate, a photosensitive film of Nano-Silver particles being formed on a surface of the substrate; providing a mask with a mesh pattern and an electrode wiring pattern to perform an exposure process to the film of Nano-Silver particles of the surface of the substrate so as to transfer the mesh pattern and electrode wiring pattern of the mask to the film of Nano-Silver particles; performing a development process to form a nontransparent sensing electrode layer and a nontransparent electrode wiring layer in the form of a mesh on the surface of the substrate; and performing a high electrical conductivity treatment and a stabilization treatment to the nontransparent sensing electrode layer on the surface of the substrate. According to the above manufacturing method of touch substrate of the present invention, the nontransparent sensing electrode layer and nontransparent electrode wiring layer are formed on the surface of the substrate at the same time. Therefore, the number of the manufacturing steps is reduced to simplify the manufacturing process. Moreover, the surface resistance is lowered and the wiring space is enlarged.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1A is a perspective view of a preferred embodiment of the touch substrate of the present invention;

FIG. 1B is an enlarged view of circled area 1B of FIG. 1A;

FIG. 1C is an enlarged view of circled area 1C of FIG. 1A;

FIG. 2 is a perspective view of another preferred embodiment of the touch substrate of the present invention;

FIG. 3 is a perspective view of the touch device of the present invention; and

FIG. 4 is a sectional view of the touch device of the present invention.

FIG. 5 is a flow chart of the manufacturing method of the touch substrate of the present invention.

### DETAILED DESCRIPTION OF THE PREFERRED EMBODIMENTS

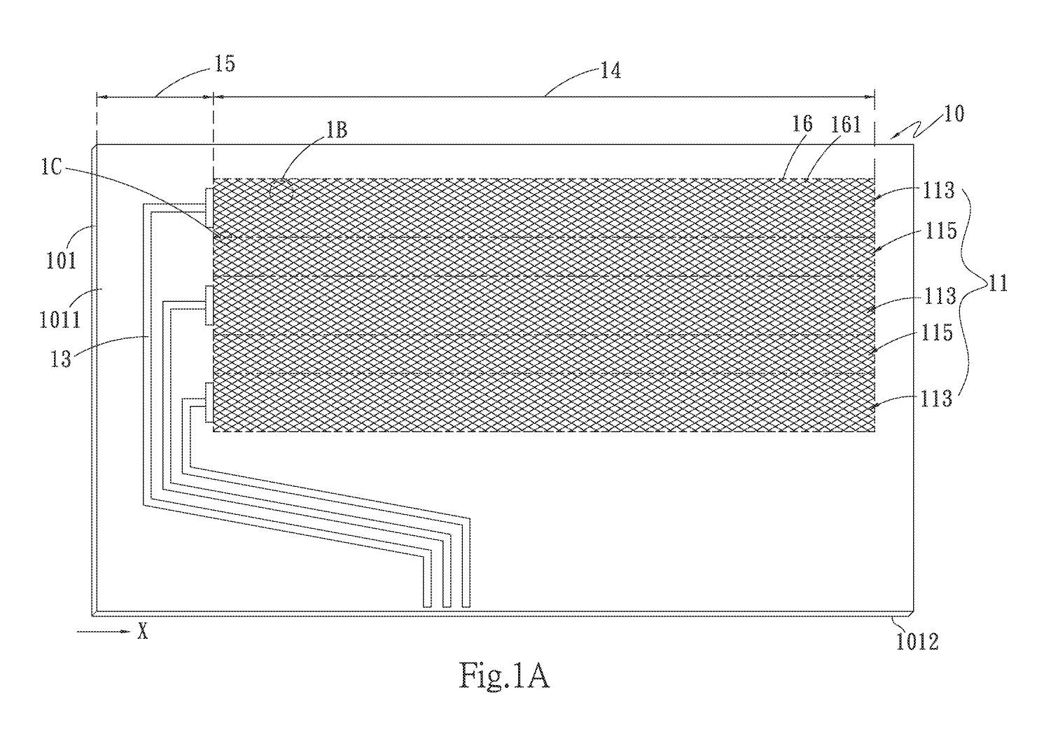

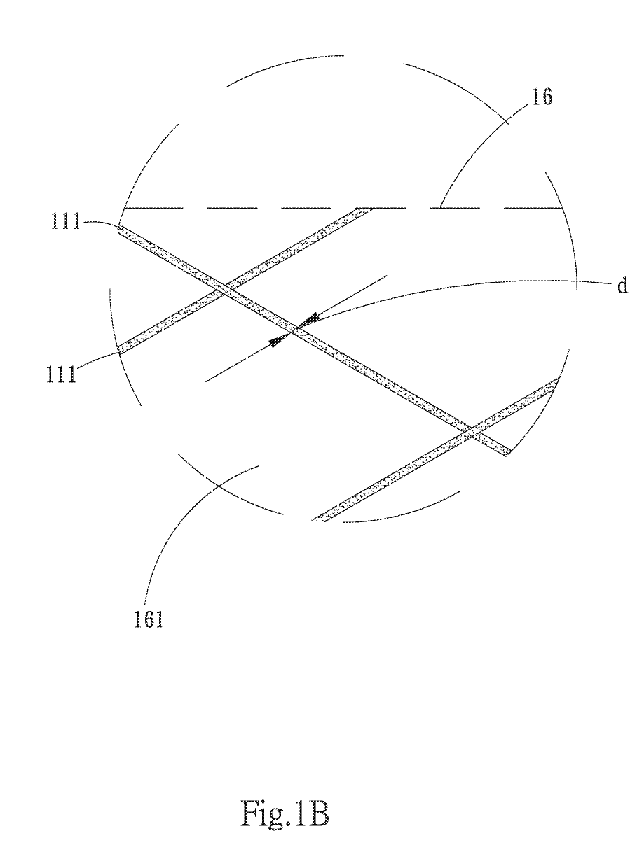

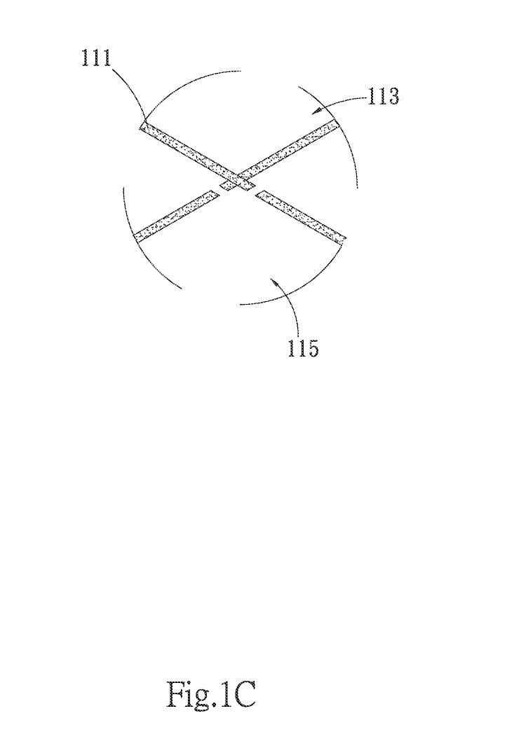

Please refer to FIG. 1A, which is a perspective view of a preferred embodiment of the touch substrate of the present invention. Also referring to FIGS. 1B, 3 and 4, the touch substrate 10 of the present invention is applied to a touch device 1 (or so-called touch panel). In practice, the touch substrate 10 is applicable to various laminated touch devices 1 such as Glass-Film-Film (GFF), Glass-Film (G1F) and Glass-Glass (GG). That is, the touch substrate 10 of the present invention is applicable to the touch device 1 instead of the substrate 101 (such as polyethylene terephthalate (PET) or glass) coated with sensing electrodes such as indium tin oxide (ITO) films or Nano-Silver-yarns.

The touch substrate 10 includes a substrate 101, at least one nontransparent (or transparent) sensing electrode layer 11 and a nontransparent (or transparent) electrode wiring layer 13. The substrate 101 is made of a flexible material. In this embodiment, the substrate 101 is, but not limited to, made of polyethylene terephthalate (PET) for illustration purposes only. The substrate 101 has a first surface 1011, a second surface 1012 opposite to the first surface 1011, a touch section 14 and a peripheral section 15. The touch section 14 is positioned at a center of the first surface 1011. The peripheral section 15 is positioned around the touch section 14.

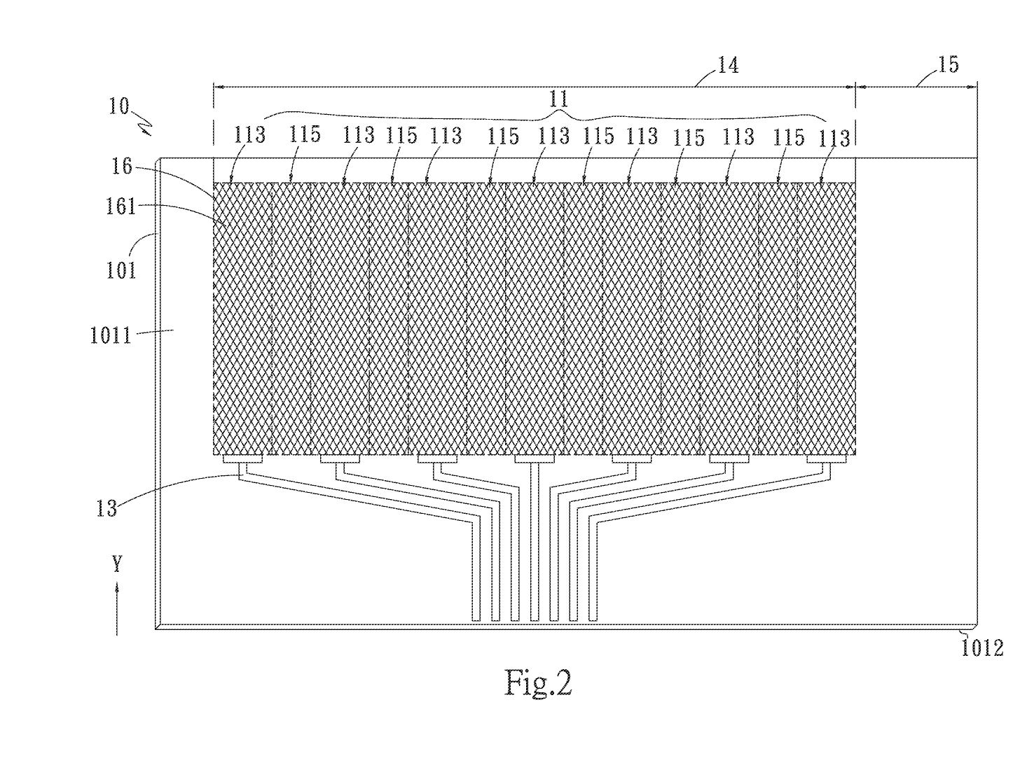

The nontransparent sensing electrode layer 11 is formed on the first surface 1011 of the substrate 101, having multiple Nano-Silver particles 111 and multiple nontransparent (or transparent) sensing blocks 113. The nontransparent sensing blocks 113 are formed of the Nano-Silver particles 111, which are arranged in the form of a mesh. That is, a photosensitive film of Nano-Silver particles is sintered on the first surface 1011 of the substrate 101. Then, sequentially by means of exposure and development processes, the nontransparent sensing blocks 113 are formed on the touch section 14 of the first surface 1011 in the form of a mesh (as shown by the phantom frame of FIG. 1A or FIG. 2). To speak in short, the nontransparent sensing electrode layer 11 is formed on the first surface 1011 of the substrate 101.

The diameter of each Nano-Silver particle 111 ranges from several nanometers to several decades of nanometers. The width d of the Nano-Silver yarns of the mesh 16 of the nontransparent sensing block 113 ranges from 1 μm to 10 μm. In this embodiment, the width d is, but not limited to, 7 μm for illustration purposes. Each small mesh 161 of the mesh 16 of the nontransparent sensing block 113 has, but not limited to, a rhombic shape. Alternatively, the small mesh 161 can be rectangular or otherwise shaped. The shape of the mesh 161 can be changed to change the permeability. In practice, according to the necessary surface resistance and transparency, a user can adjustably design the width d of the mesh 16 of the nontransparent sensing electrode layer 11 and the shape and size of the small mesh 161 of the mesh 16 so as to achieve low surface resistance (about 25 ohms/□) and high transparency).

Please now refer to FIGS. 1A, 1B and 2. A nontransparent (or transparent) non-sensing block 115 is positioned between each two adjacent nontransparent sensing blocks 113. The nontransparent non-sensing blocks 115 are formed of multiple Nano-Silver particles, which are arranged in the form of a mesh. That is, the nontransparent non-sensing blocks 115 are formed on the touch section 14 of the first surface 1011 in the form of a mesh (as shown by the phantom frame of FIG. 1A or FIG. 2) and positioned between the nontransparent sensing blocks 113. The nontransparent non-sensing blocks 115 are not electrically connected with the adjacent nontransparent sensing blocks 113. In other words, no current passes through the nontransparent non-sensing blocks 115 so that the nontransparent non-sensing blocks 115 cannot provide the effect of sensing electrodes. The nontransparent non-sensing blocks 115 prevent the nontransparent sensing blocks 113 from being easily observed so as to achieve a visual balance effect. In this embodiment, the nontransparent non-sensing blocks 115 and the adjacent nontransparent sensing blocks 113 are separated from each other by, but not limited to, 7 μm (as shown in FIG. 1C) and are electrically disconnected from each other. In practice, the distance between the nontransparent non-sensing blocks 115 and the adjacent nontransparent sensing blocks 113 is previously adjustable according to the visual requirement and sensitivity.

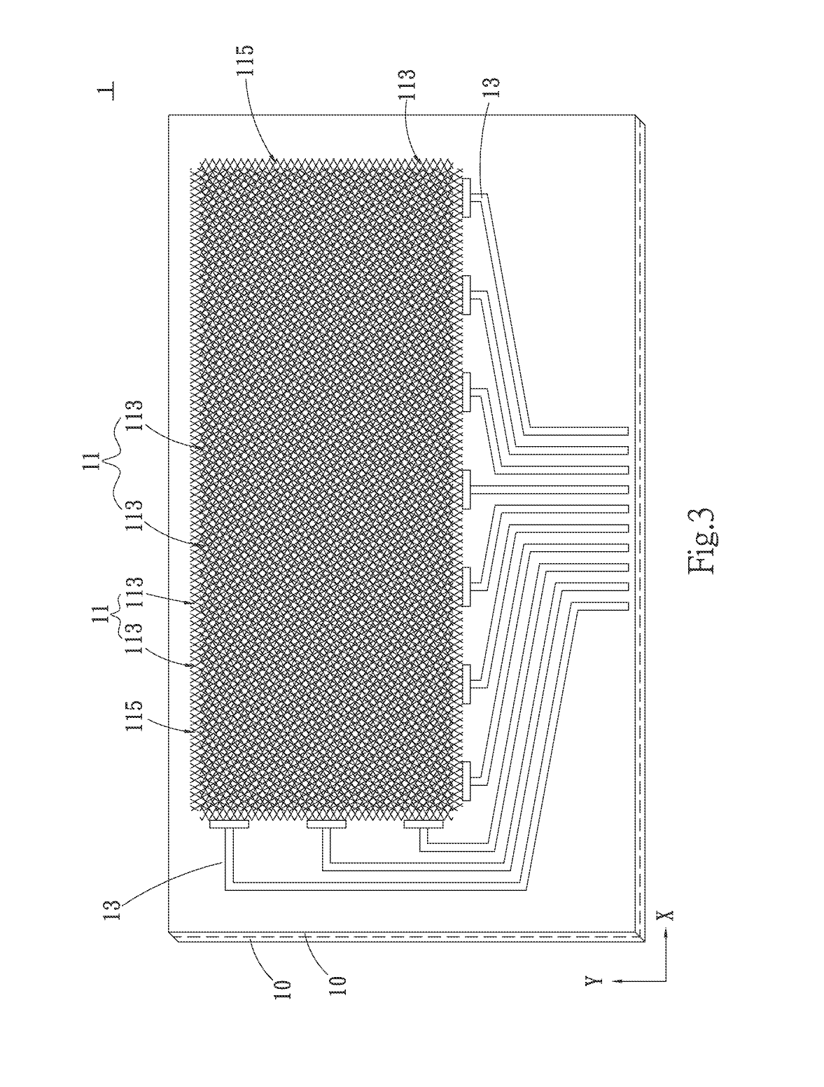

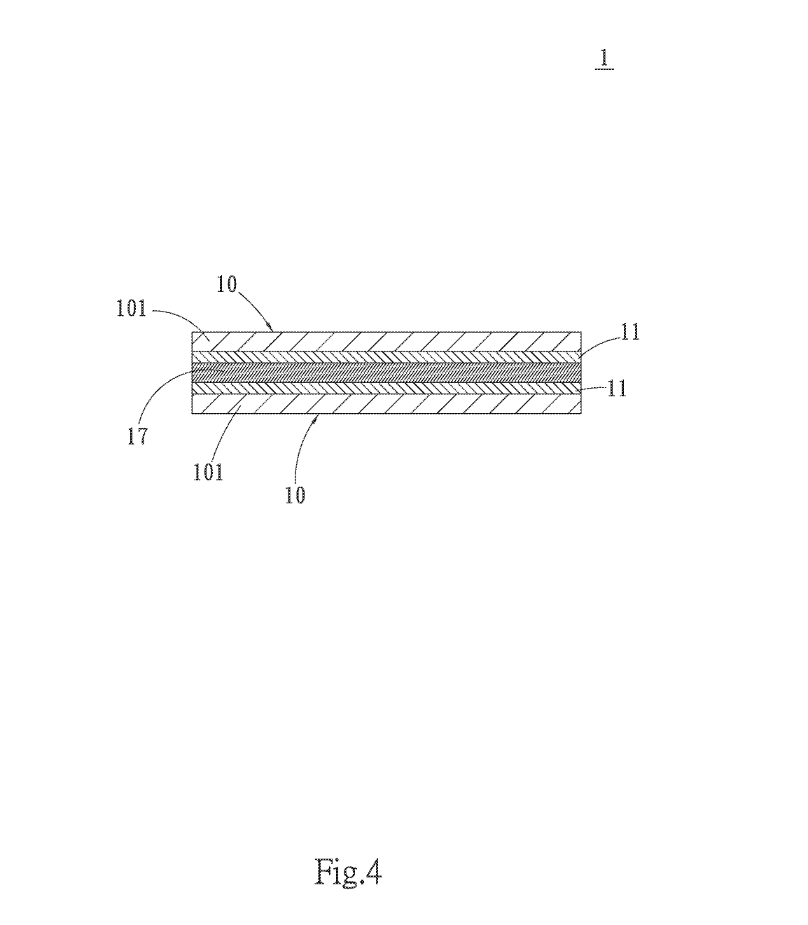

Moreover, in this embodiment, the nontransparent sensing blocks 113 are arranged on the first surface 1011 of the substrate 101 in a first direction X, that is, X-axis direction (as shown by the phantom frame of FIG. 1A). However, alternatively, the nontransparent sensing blocks 113 can be also arranged on the first surface 1011 of the substrate 101 in a second direction Y, that is, Y-axis direction (as shown by the phantom frame of FIG. 2). Alternatively, as shown in FIGS. 3 and 4, the two substrates 101 of the touch device 1 are respectively provided with nontransparent sensing blocks 113 in the first direction X and the second direction Y. In addition, an optical clear adhesive 17 (such as OCR) is disposed between the two substrates.

The nontransparent electrode wiring layer 13 is formed on the periphery of the first surface 1011 correspondingly in adjacency to and in connection with the nontransparent sensing electrode layer 11. That is, the nontransparent electrode wiring layer 13 is formed on the peripheral section 15 of the first surface 1011 and correspondingly connected with the nontransparent sensing electrode layer 11 on the touch section 14.

According to the above arrangement of the touch substrate 10 of the present invention, the manufacturing process is simplified and the surface resistance is lowered. Moreover, the wiring space is enlarged.

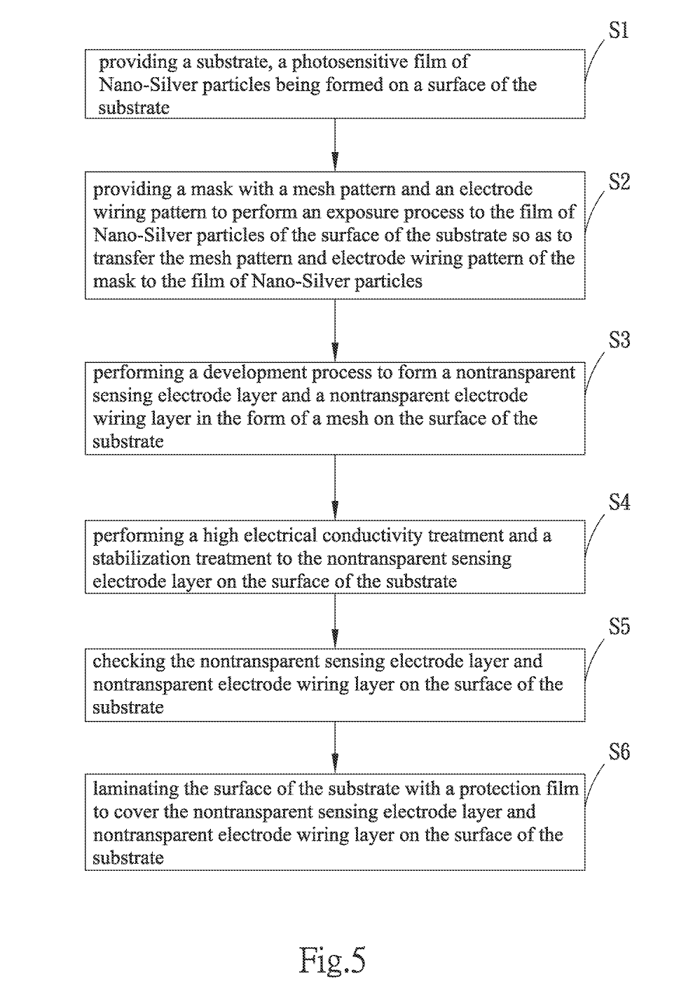

Please now refer to FIG. 5, which is a flow chart of the manufacturing method of the first preferred embodiment of the touch substrate of the present invention. Also referring to FIGS. 1A and 1B, the manufacturing method of the touch substrate of the present invention includes steps of:

S1. providing a substrate, a photosensitive film of Nano-Silver particles being formed on a surface of the substrate, a substrate 101 being provided, a photosensitive film of Nano-Silver particles being formed on a surface (the first surface 1011 of the first preferred embodiment) of the substrate 101, the substrate 101 being made of a flexible material, in this embodiment, the substrate 101 being made of polyethylene terephthalate (PET) for illustration purposes, the film of Nano-Silver particles being composed of multiple Nano-Silver particle, each Nano-Silver particle having a diameter ranging from several nanometers to several decades of nanometers;

S2. providing a mask with a mesh pattern and an electrode wiring pattern to perform an exposure process to the film of Nano-Silver particles of the surface of the substrate so as to transfer the mesh pattern and electrode wiring pattern of the mask to the film of Nano-Silver particles, a mask with a mesh pattern and an electrode wiring pattern being provided, the mask being overlaid on the film of Nano-Silver particles of the surface (the first surface 1011) of the substrate 101 to perform an exposure process, after the exposure process is completed, the mesh pattern and electrode wiring pattern of the mask being transferred to the film of Nano-Silver particles of the surface (the first surface 1011) of the substrate 101;

S3. performing a development process to form a nontransparent sensing electrode layer and a nontransparent electrode wiring layer in the form of a mesh on the surface of the substrate, a development process being performed to leave the necessary mesh pattern and electrode wiring pattern on the film of Nano-Silver particles of the surface (the first surface 1011) of the substrate 101 off the remaining parts, then the nontransparent sensing electrode layer 11 and nontransparent electrode wiring layer 13 on the surface (the first surface 1011) of the substrate 101 being washed with warm water, then the surface of the substrate 101 being blackened to make the nontransparent sensing electrode layer 11 and nontransparent electrode wiring layer 13 on the surface (the first surface 1011) of the substrate 101 more unobvious, then the blackening liquid remaining on the surface (the first surface 1011) of the substrate 101 being washed off with warm water to form the nontransparent sensing electrode layer 11 and nontransparent electrode wiring layer 13 on the first surface 1011 of the substrate 101 in the form of a mesh, the nontransparent electrode wiring layer 13 being electrically connected with the nontransparent sensing electrode layer 11, the nontransparent sensing electrode layer 11 having multiple nontransparent sensing blocks 113 in the form of a mesh, the nontransparent sensing blocks 113 being formed on the touch section 14 of the first surface 1011, the nontransparent electrode wiring layer 13 being formed on the peripheral section 15 of the first surface 1011;

S4. performing a high electrical conductivity treatment and a stabilization treatment to the nontransparent sensing electrode layer on the surface of the substrate, a high electrical conductivity treatment being performed to the nontransparent sensing electrode layer 11 on the first surface 1011 of the substrate 101 to enhance the electrical conductivity of the nontransparent sensing electrode layer 11 on the first surface 1011, then the high electrical conductivity treatment liquid remaining on the surface (the first surface 1011) being washed off with warm water, then a stabilization treatment being performed to stabilize the electrical conductivity of the nontransparent sensing electrode layer 11 on the first surface 1011, then the stabilization treatment solvent remaining on the surface (the first surface 1011) being washed off with warm water;

S5. checking the nontransparent sensing electrode layer and nontransparent electrode wiring layer on the surface of the substrate, the nontransparent sensing electrode layer 11 and nontransparent electrode wiring layer 13 of the surface (the first surface 1011) of the substrate 101 being electrically and visually checked to see whether the circuit is opened or whether there is a short-circuit or a poor appearance; and

S6. laminating the surface of the substrate with a protection film to cover the nontransparent sensing electrode layer and nontransparent electrode wiring layer on the surface of the substrate, after checked, the first surface 1011 of the substrate 101 being laminated with a protection film (not shown) to cover and protect the nontransparent sensing electrode layer 11 and nontransparent electrode wiring layer 13 on the first surface 1011 of the substrate 101.

According to the above manufacturing method of touch substrate of the present invention, the nontransparent sensing electrode layer 11 and nontransparent electrode wiring layer 13 can be formed on the surface of the substrate 101 at the same time. Therefore, the number of the manufacturing steps is reduced to simplify the manufacturing process. Moreover, the surface resistance is lowered and the wiring space is enlarged.

In conclusion, in comparison with the conventional device, the present invention has the following advantages:

1. The number of the manufacturing steps is reduced to simplify the manufacturing process and the surface resistance is lowered.

2. The wiring space is enlarged.

The present invention has been described with the above embodiments thereof and it is understood that many changes and modifications in the above embodiments can be carried out without departing from the scope and the spirit of the invention that is intended to be limited only by the appended claims.

What is claimed is:

1. A manufacturing method of touch substrate, comprising steps of:
providing a substrate, a photosensitive film of Nano-Silver particles being formed on a surface of the substrate;
providing a mask with a mesh pattern and an electrode wiring pattern to perform an exposure process to the film of Nano-Silver particles of the surface of the substrate so as to transfer the mesh pattern and electrode wiring pattern of the mask to the film of Nano-Silver particles;
performing a development process to form a nontransparent sensing electrode layer and a nontransparent electrode wiring layer in the form of a mesh on the surface of the substrate; and
performing a high electrical conductivity treatment and a stabilization treatment to the nontransparent sensing electrode layer on the surface of the substrate.

2. The manufacturing method of touch substrate as claimed in claim 1, wherein in the step of performing a development process, the nontransparent sensing electrode layer and nontransparent electrode wiring layer on the surface of the substrate are washed with warm water, then the surface of the substrate being blackened to make the nontransparent sensing electrode layer and nontransparent electrode wiring layer on the surface of the substrate more unobvious, then the blackening liquid remaining on the surface of the substrate being washed off with warm water.

3. The manufacturing method of touch substrate as claimed in claim 2, wherein after the step of performing a high electrical conductivity treatment and a stabilization treatment to the nontransparent sensing electrode layer on the surface of the substrate, the manufacturing method of touch substrate further comprises a step of checking the nontransparent sensing electrode layer and nontransparent electrode wiring layer on the surface of the substrate and a step of laminating the surface of the substrate with a protection film to cover the nontransparent sensing electrode layer and nontransparent electrode wiring layer on the surface of the substrate.

4. The manufacturing method of touch substrate as claimed in claim 1, wherein the substrate is made of flexible material.

5. The manufacturing method of touch substrate as claimed in claim 1, wherein the film of Nano-Silver particles is composed of multiple Nano-Silver particles, each Nano-Silver particle having a diameter ranging from several nanometers to several decades of nanometers.
